(19) United States
(12) Patent Application Publication
(10) Pub. No.: US 2023/0411956 A1
(43) Pub. Date: Dec. 21, 2023

(54) CIRCUIT TECHNIQUES FOR ENHANCED ELECTROSTATIC DISCHARGE (ESD) ROBUSTNESS

(71) Applicant: QUALCOMM Incorporated, San Diego, CA (US)

(72) Inventors: Sreeker DUNDIGAL, San Diego, CA (US); Reza JALILIZEINALI, San Marcos, CA (US); Krishna Chaitanya CHILLARA, Del Mar, CA (US); Wen-Yi CHEN, Folsom, CA (US)

(21) Appl. No.: 18/364,164

(22) Filed: Aug. 2, 2023

Related U.S. Application Data
(62) Division of application No. 17/355,016, filed on Jun. 22, 2021, now abandoned.
(60) Provisional application No. 63/046,311, filed on Jun. 30, 2020.

(51) Int. Cl. H02H 9/04; H01L 27/02; H03K 17/082

(52) U.S. Cl. CPC H02H 9/046; H02H 1/0007; H03K 17/0822; H01L 27/0292

(57) ABSTRACT

Exemplary electrostatic discharge (ESD) circuit schemes are provided according to various aspects of the present disclosure. In certain aspects, a current path is created during an ESD event that causes current to flow through a resistor coupled to a protected transistor (e.g., a driver transistor). The current through the resistor creates a voltage drop across the resistor, which reduces the voltage seen by the protected transistor. In certain aspects, the current path is provided by an ESD circuit coupled to a node between the resistor and the transistor. In certain aspects, the current path is created by turning on the transistor during the ESD event with a trigger device.

### RELATED APPLICATION

This application is a divisional of U.S. application Ser. No. 17/355,016, filed on Jun. 22, 2021, which claims priority under 35 U.S.C. § 119(e) to U.S. Provisional Application No. 63/046,311 filed on Jun. 30, 2020, the entire specifications of which are incorporated herein by reference.

### BACKGROUND

### Field

Aspects of the present disclosure relate generally to electrostatic discharge (ESD) protection, and more particularly, to on-chip ESD protection circuits.

### Background

Electronic components on a chip are susceptible to damage from an electrostatic discharge (ESD) event. For example, an ESD event may damage or destroy the gate oxide, metallization, and/or PN junction of an electronic component on the chip. Damage caused by ESD events may reduce manufacturing yields and/or lead to operational failures of electronic components. Accordingly, a chip typically includes one or more ESD protection circuits to protect electronic components on the chip against ESD events.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a pad and an interface circuit coupled to the pad. The interface circuit includes a transistor and a resistor coupled between the pad and the transistor. The chip further includes an electrostatic discharge (ESD) circuit coupled to a node between the resistor and the transistor, wherein the ESD circuit is configured to provide a current path between the node and a first bus during an ESD event.

A second aspect relates to a chip. The chip includes a pad and an interface circuit coupled to the pad, wherein the interface circuit includes a transistor coupled to the pad. The chip also includes a trigger device, and a pass circuit having a first input coupled to the trigger device, and an output coupled to a gate of the transistor.

A third aspect relates to a method of electrostatic discharge (ESD) protection for an interface circuit coupled to a pad. The interface circuit includes a transistor and a resistor coupled between the pad and the transistor. The method incudes, during an ESD event, providing a current path between a node and a bus, wherein the node is between the resistor and the transistor.

A fourth aspect relates to a method of electrostatic discharge (ESD) protection for an interface circuit coupled to a pad. The interface circuit includes a transistor and a resistor coupled between the pad and the transistor. The method includes detecting an ESD event, and, in response to detecting the ESD event, turning on the transistor.

A fifth aspect related to a method of electrostatic discharge (ESD) protection for an interface circuit coupled to a pad. The interface circuit includes a transistor coupled to the pad. The method includes, passing a drive signal to a gate of the transistor, generating a trigger signal based on an ESD event, and passing the trigger signal to the gate of the transistor.

### BRIEF DESCRIPTION OF THE DRAWINGS

FIG. 1 shows an example of a chip including an ESD protection circuit according to certain aspects of the present disclosure.

FIG. 2 shows an example of a current path during a negative charged device model (CDM) event according to certain aspects of the present disclosure.

FIG. 3 shows an example of a secondary ESD circuit including one or more diodes according to certain aspects of the present disclosure.

FIG. 4A shows another example of a secondary ESD circuit including one or more diodes according to certain aspects of the present disclosure.

FIG. 4B shows an example of a secondary ESD circuit including stacked diodes according to certain aspects of the present disclosure.

FIG. 5 shows an example of a secondary ESD circuit including one or more dummy transistors functioning as diodes according to certain aspects of the present disclosure.

FIG. 6 shows an example of a secondary ESD circuit including a clamp device according to certain aspects of the present disclosure.

FIG. 7 shows an example in which a trigger device is shared by two clamp transistors according to certain aspects of the present disclosure.

FIG. 8 shows an exemplary implementation of a trigger device according to certain aspects of the present disclosure.

FIG. 9 shows an example in which multiple clamp transistors share a trigger device according to certain aspects of the present disclosure.

FIG. 10 shows an example in which ESD protection is incorporated into a driver according to certain aspects of the present disclosure.

FIG. 11 shows another example in which ESD protection is incorporated into a driver according to certain aspects of the present disclosure.

FIG. 12 shows an example in which ESD protection is incorporated into impedance matching networks according to certain aspects of the present disclosure.

FIG. 13 conceptually generalizes exemplary ESD protection schemes according to various aspects of the present disclosure

FIG. 14 shows an example in which driver transistors share a common resistor according to certain aspects of the present disclosure.

FIG. 15 shows an example of an ESD protection circuit including a forward diode from pad to ground according to certain aspects of the present disclosure.

FIG. 16 shows another example of an ESD protection circuit including a stack of forward diodes from pad to ground according to certain aspects of the present disclosure.

FIG. 17 is a flow chart illustrating an exemplary method of ESD protection for an interface circuit according to certain aspects of the present disclosure.

FIG. 18 is a flow chart illustrating another exemplary method of ESD protection for an interface circuit according to certain aspects of the present disclosure.

FIG. 19 is a flow chart illustrating yet another exemplary method of ESD protection for an interface according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A chip typically includes one or more ESD protection circuits to protect electronic components on the chip against ESD events. An ESD event may occur, for example, when a charged object makes contact with an input/output (I/O) pad of the chip (e.g., during handling of the chip). An ESD event may also occur, for example, when the chip acquires charge and then discharges to an object making contact with an I/O pad of the chip. An ESD protection circuit may include one or more clamp devices, one or more diodes, or a combination thereof.

A chip may undergo one or more ESD qualification tests based on a human body model (HBM) and/or a charged device model (CDM) to evaluate the ESD robustness of the chip. During an HBM test, a capacitor (e.g., 100 pF capacitor) is charged to a high voltage (e.g., one or more kilovolts). Once the capacitor is fully charged, the capacitor is coupled to an I/O pad of the chip through a series resistor to simulate an ESD event caused by the transfer of charge from a human to the chip. In this example, the chip fails the HBM test if one or more electronic components on the chip suffers an ESD failure.

During a CDM test, the chip is positively or negatively charged. The chip is then discharged through a grounded pin that makes contact with an I/O pad of the chip. In this example, the chip fails the CDM test if one or more electronic components on the chip suffers an ESD failure.

Integrated circuit (IC) chips in advanced technology nodes may be required to pass ESD qualification tests (e.g., HBM +/−1 kV and CDM +/−250V). As technology continues to scale down and data rates continue to increase, CDM ESD has become a major challenge for high speed I/O pads (i.e., interface pins), especially for FinFet process nodes. To achieve high data speeds and low power, thin oxide transistors are being used in interface circuits (e.g., drivers). The ESD failure voltage of thin oxide transistors has been going down with advances in technology, making these transistors more vulnerable to ESD.

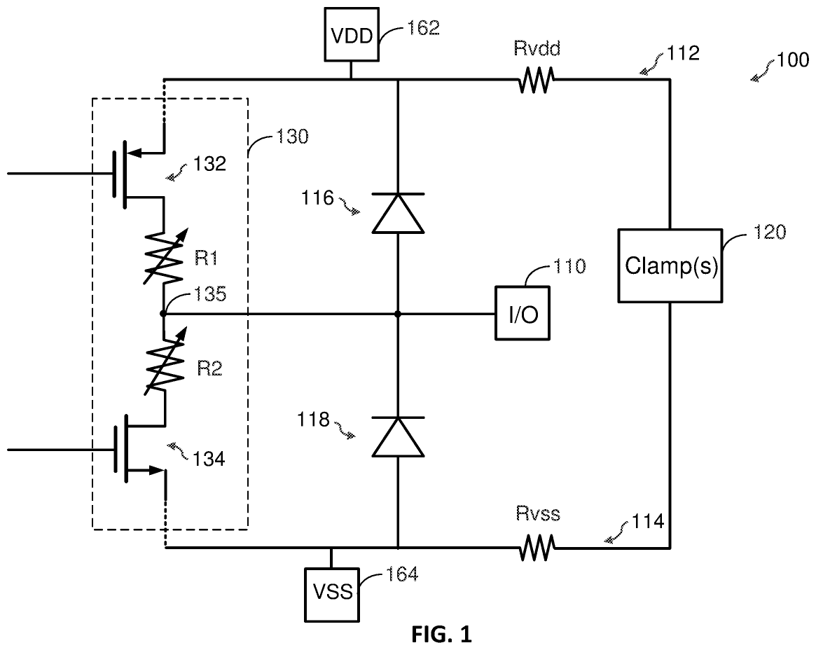

FIG. 1 shows an example of a chip 100 including an ESD protection circuit. In this example, the chip 100 includes an I/O pad 110 and a driver 130 coupled to the I/O pad 110. The driver 130 includes driver transistors 132 and 134, a first resistor R1, and a second resistor R2. In the example in FIG. 1, the first resistor R1 is coupled between the output 135 of the driver 130 and the driver transistor 132, and the second resistor R2 is coupled between the output 135 of the driver 130 and the driver transistor 134. During normal operation, the resistors R1 and R2 are used for impedance matching and may be implemented with variable resistors. Also, during normal operation, the driver transistor 132 may function as a pull-up transistor and the driver transistor 134 may function as a pull-down transistor. The dotted lines in FIG. 1 indicate that one or more additional transistors may be stacked with the transistors 132 and 134 in some implementations. The driver transistor 134 is often implemented with an n-type metal oxide semiconductor (NMOS) transistor. The driver transistor 132 is often implemented with a p-type metal oxide semiconductor (PMOS) transistor. However, the driver transistor 132 may also be implemented with an NMOS transistor in some applications. The gates of the transistors 132 and 134 may be driven by a predriver (not shown) during normal operation.

The ESD protection circuit includes a first diode 116 coupled between the I/O pad 110 and a VDD bus 112, and a second diode 118 coupled between the I/O pad 110 and a VSS bus 114. As discussed further below, the first diode 116 provides a current path from the I/O pad 110 to the VDD bus 112 during a negative CDM ESD event, and the second diode 118 provides a current path from the VSS bus 114 to the I/O pad 1_10 during a positive CDM ESD event. The diodes 116 and 118 may also provide current paths for other types of ESD events.

The ESD protection circuit also includes one or more clamp devices 120 coupled between the VDD bus 112 and the VSS bus 114. The clamp device 120 may include a clamp transistor and a trigger device (e.g., resistor-capacitor (RC) trigger device), in which the trigger device is configured to turn on the clamp transistor during an ESD event.

The ESD protection circuit can provide the chip 100 with ESD protection during handling and packaging before the VDD bus 112 is coupled to a power source via the VDD pad 162, the VSS bus 114 is coupled to a ground via the VSS pad 164, and/or the I/O pad 110 is coupled to a transmission line. The ESD protection circuit can also provide the chip 100 with ESD protection after packaging.

During an ESD event, the ESD protection circuit needs to clamp the I/O pad voltage (“Vpad”) to a safe voltage level to prevent damage to transistors (e.g., transistors and 132 and 1343 coupled to the I/O pad 110. This is becoming more challenging as thin oxide transistors are being used to achieve higher data speeds. The ESD failure voltage of these thin oxide transistors has been going down with advances in technology, making these transistors more vulnerable to ESD. For example, in current advanced technology nodes, the ESD failure voltage of thin oxide transistors may be approximately 3V for Ins transmission line pulse (TLP) widths, which is commonly used to represent the pulse width of CDM ESD discharge current waveform. Thus, the ESD protection circuit needs to clamp the pad voltage Vpad to lower voltage levels during ESD events to prevent damaging these transistors.

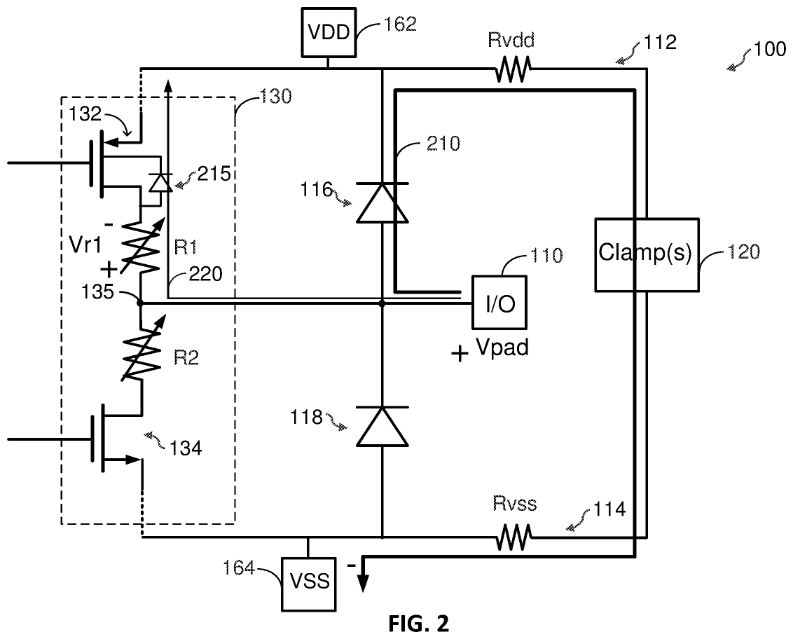

FIG. 2 shows a primary current path 210 through the ESD protection circuit for a negative CDM ESD event. In this case, the ESD current flows from the I/O pad 110 to the substrate through the first diode 116, the VDD bus 112, the clamp device 120, and the VSS bus 114. The substrate may be capacitively coupled to a field plate.

In this example, the pad voltage Vpad includes the turn-on offset voltage of the diode 116 and the turn-on offset voltage of the clamp device 120. The pad voltage Vpad also includes the IR voltage drop across the resistance of the diode 116, the resistance of the VDD bus 112, the resistance of the clamp device 120, and the resistance of the VSS bus 114. In FIG. 2, the resistance of the VDD bus 112 and the resistance of the VSS bus 114 are represented by resistances Rvdd and Rvss, respectively. The resistances of the VDD bus 112 and the VSS bus 114 may be referred to collectively as the bus resistance.

As shown in FIG. 2, during the negative CDM ESD event, a parasitic P+/NW drain-body diode 215 of the driver transistor 132 may provide a secondary current path 220 from the I/O pad 110 to the VDD bus 112. The body may be connected to VDD and/or the source of the driver transistor 132. The current flowing through the secondary current path 220 produces a voltage drop Vr1 across the first resistor R1. This voltage drop reduces the voltage seen at the driver transistor 132, which may help make the driver transistor 132 less vulnerable to ESD failure during the negative CDM ESD event.

During the negative CDM ESD event, the pad voltage Vpad is seen by the driver transistor 134 (e.g., NMOS transistor). As a result, the driver transistor 134 is more vulnerable to ESD failure. Negative CDM is typically more challenging to pass. Therefore, exemplary circuit techniques for enhancing ESD protection are discussed below according to aspects of the present disclosure for the example of negative CDM. However, it is to be appreciated that the exemplary circuit techniques are also applicable to positive CDM and other types of ESD events, as discussed further below.

The sum of the turn-on offset voltage of the diode 116 and the turn-on offset voltage of the clamp device 120 can easily reach close to 2V, which may not scale down rapidly with technology node. For a protected transistor (e.g., transistor 134) that fails at 3V, this leaves a very small voltage overhead for the IR voltage drop of only 1V. If the peak CDM current is 5 A. then the maximum total resistance for this case is 0.2Ω. Thus, in this example, the sum of the diode-on resistance, the bus resistance, and the clamp resistance needs to be less than 0.2Ω, which is difficult to achieve in practice. Accordingly, circuit techniques for enhancing the CDM robustness of a protected circuit while maintaining high data rates and performance are desirable.

In certain aspects, ESD protection is enhanced by adding a secondary ESD circuit configured to provide a secondary current path for the resistor R2. During a negative CDM event, current flowing through the secondary current path flows through resistor R2 producing a voltage drop Vr2 across the resistor R2. This voltage drop Vr2 reduces the voltage seen at the driver transistor 134 during a negative CDM ESD event, and therefore reduces the voltage stress on the driver transistor 134. Exemplary implementations of the secondary ESD circuit are discussed below according to various aspects of the present disclosure.

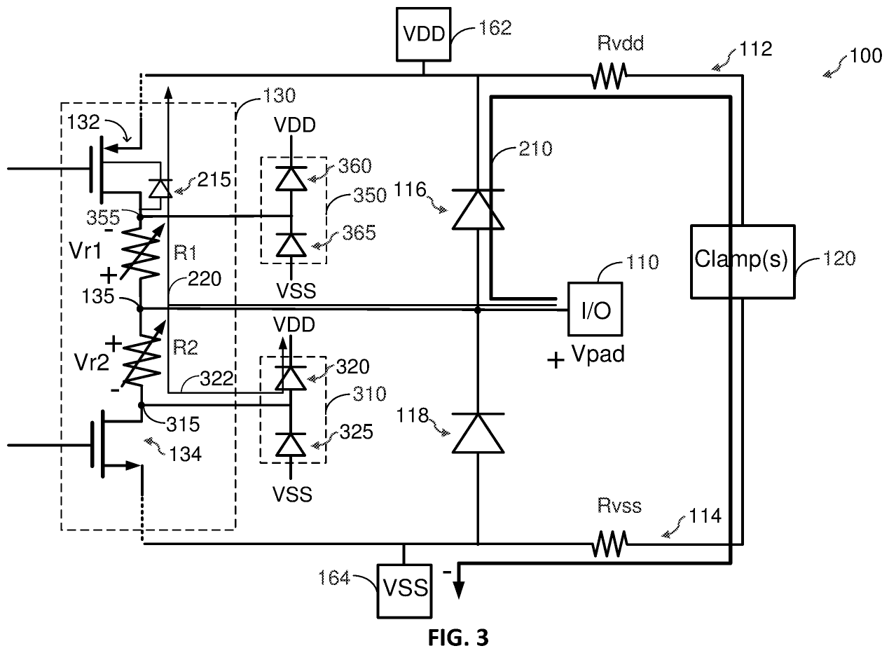

FIG. 3 shows an exemplary implementation of a secondary ESD circuit 310 according to certain aspects. In the example in FIG. 3, the secondary ESD circuit 310 is coupled to a node 315 between the resistor R2 and the driver transistor 134 (e.g., NMOS transistor). The secondary ESD circuit 310 includes a first diode 320, in which the anode of the first diode 320 is coupled to the node 315 and the cathode of the first diode 320 is coupled to the VDD bus 112. The first diode 320 is coupled in series with the resistor R2.

During a negative CDM ESD event, the first diode 320 turns on and provides a secondary current path 322 from node 315 to the VDD bus 112. Because the first diode 320 is coupled in series with the resistor R2, the current flowing through the secondary current path 322 flows through the resistor R2, producing a voltage drop Vr2 across the resistor R2. The voltage drop Vr2 across the resistor R2 lowers the voltage seen at the drain of the driver transistor 134 to Vpad minus Vr2, thereby enhancing the ESD protection of the driver transistor 134.

The secondary ESD circuit 310 may also include a second diode 325, in which the anode of the second diode 325 is coupled to the VSS bus 114 and the cathode of the second diode 325 is coupled to the node 315. In this example, the second diode 325 is configured to provide a secondary current path from the VSS bus 114 to the resistor R2 (e.g., during a positive CDM ESD event).

It is to be appreciated that the first diode 320 and the second diode 325 can exist independently. For example, the secondary ESD circuit 310 may include the first diode 320, but not the second diode 325. In another example, the secondary ESD circuit 310 may include the second diode 325, but not the first diode 320. In another example, the secondary ESD circuit 310 may include both diodes 320 and 325.

In some implementations, the chip 100 may also include another secondary ESD circuit 350 coupled to a node 355 between the resistor R1 and the driver transistor 132. The secondary ESD circuit 350 includes a first diode 360, in which the anode of the first diode 360 is coupled to the node 355 and the cathode of the first diode 360 is coupled to the VDD bus 112. The first diode 360 is coupled in series with the resistor R1.

During a negative CDM ESD event, the first diode 360 turns on and provides a secondary current path from node 355 to the VDD bus 112. Because the first diode 360 is coupled in series with the resistor R1, the current flowing through the secondary current path flows through the resistor R1. This current may be in addition to the current flowing through the resistor R1 to the drain-body diode 215. In this example, the additional secondary current flow provided by the first diode 360 increases the voltage drop Vr1 across the resistor R1, which further lowers the voltage seen at the drain of the driver transistor 132. It is to be appreciated that the first diode 360 may also be used in cases where the drain-body diode 215 is not present.

The secondary ESD circuit 350 may also include a second diode 365, in which the anode of the second diode 365 is coupled to the VSS bus 114 and the cathode of the second diode 365 is coupled to the node 355. In this example, the second diode 365 is configured to provide a secondary current path from the VSS bus 114 to the resistor R1 (e.g., during a positive CDM ESD event).

It is to be appreciated that the secondary ESD circuits 310 and 350 can exist independently. For example, the chip 100 may include one of the secondary ESD circuits 310 and 350 or the chip 100 may include both of the secondary ESD circuits 310 and 350.

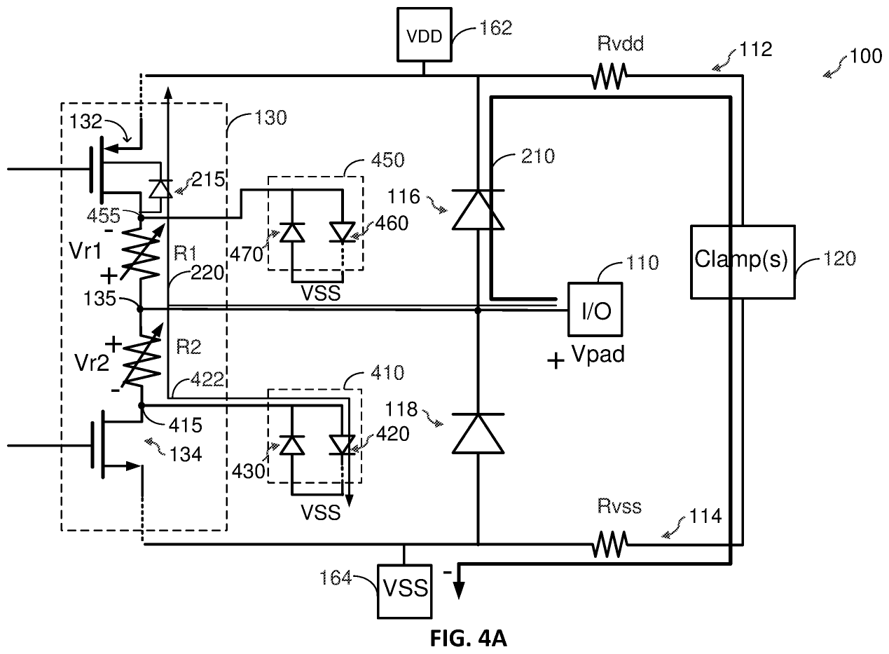

FIG. 4A shows another exemplary implementation of a secondary ESD circuit 410 according to certain aspects. In the example in FIG. 4A, the secondary ESD circuit is coupled to a node 415 between the resistor R2 and the driver transistor 134 (e.g., NMOS transistor). The secondary ESD circuit 410 includes a first diode 420, in which the anode of the first diode 420 is coupled to the node 415 and the cathode of the first diode 420 is coupled to the VSS bus 114. In other words, the first diode 420 is in the forward direction from the node 415 to the VSS bus 114 such that the first diode 420 is forward biased when the potential of node 415 is higher than the potential of the VSS bus 114. The first diode 420 is coupled in series with the resistor R2.

During a negative CDM ESD event, the first diode 420 turns on and provides a secondary current path 422 from node 415 to the VSS bus 114. Since the first diode 420 is coupled in series with the resistor R2, the current flowing through the secondary current path 422 flows through the resistor R2, producing a voltage drop Vr2 across the resistor R2. The voltage drop Vr2 across the resistor R2 lowers the voltage seen at the drain of the driver transistor 134 to Vpad minus Vr2, thereby enhancing the ESD protection of the driver transistor 134.

The dotted line between the first diode 420 and the VSS bus 114 indicates that one or more additional diodes may be stacked with the first diode 420. Thus, in some implementations, the secondary ESD circuit 410 may include two or more stacked diodes coupled between the node 415 and the VSS bus 114. Two or more stacked diodes may be used to increase the voltage needed to turn on the secondary current path. This may be done, for example, to prevent the secondary current path from unintentionally turning on during normal operation of the driver 130 in cases where the turn-on voltage of a single diode is lower than the voltage swing at the drain of the driver transistor 134 during normal operation.

In this regard, FIG. 4B shows an example in which the secondary ESD circuit 410 also includes a second diode 425 coupled in series with the first diode 420. In this example, the first diode 420 and the second diode 425 provide a secondary current path from the node 415 to the VSS bus 114 during a negative CDM ESD event. Also, in this example, the turn-on voltage of the secondary current path 422 is the sum of the turn-on voltage of the first diode 420 and the turn-on voltage of the second diode 425. The diodes 420 and 425 are in the forward direction from the node 415 to the VSS bus 114 such that the diodes 420 and 425 are forward biased when the potential of node 415 is higher than the potential of the VSS bus 114.

The secondary ESD circuit 410 may also include a third diode 430, in which the anode of the third diode 430 is coupled to the VSS bus 114 and the cathode of the third diode 430 is coupled to the node 415. In this example, the third diode 430 is configured to provide a secondary current path from the VSS bus 114 to the resistor R2 (e.g., during a positive CDM ESD event). It is to be appreciated that the third diode 430 may be omitted in some implementations.

Referring back to FIG. 4A, in some implementations, the chip 100 may include another exemplary secondary ESD circuit 450 coupled to a node 455 between the resistor R1 and the driver transistor 132. The secondary ESD circuit 450 includes a first diode 460, in which the anode of the first diode 460 is coupled to the node 455 and the cathode of the first diode 460 is coupled to the VSS bus 114. The first diode 460 is coupled in series with the resistor R1.

During a negative CDM ESD event, the first diode 460 turns on and provides a secondary current path from node 455 to the VSS bus 114. Because the first diode 460 is coupled in series with the resistor R1, the current flowing through the secondary current path flows through the resistor R1. This current may be in addition to the current flowing through the resistor R1 to the drain-body diode 215. In this example, the additional secondary current flow provided by the first diode 460 increases the voltage drop Vr1 across the resistor R1, which further lowers the voltage seen at the drain of the driver transistor 132. It is to be appreciated that the first diode 460 may also be used in cases where the drain-body diode 215 is not present.

The dotted line between the first diode 460 and the VSS bus 114 indicates that one or more additional diodes may be stacked with the first diode 460. In this regard, FIG. 4B shows an example in which the secondary ESD circuit 450 also includes a second diode 465 coupled in series with the first diode 460 between the node 455 and the VSS bus 114. The diodes 460 and 465 are in the forward direction from the node 455 to the VSS bus 114 such that the diodes 460 and 465 are forward biased when the potential of node 455 is higher than the potential of the VSS bus 114.

The secondary ESD circuit 450 may also include a third diode 470, in which the anode of the third diode 470 is coupled to the VSS bus 114 and the cathode of the third diode 470 is coupled to the node 455. In this example, the third diode 470 is configured to provide a secondary current path from the VSS bus 114 to the resistor R1 (e.g., during a positive CDM ESD event). It is to be appreciated that the third diode 470 may be omitted in some implementations.

It is to be appreciated that the secondary ESD circuits 410 and 450 can exist independently. For example, the chip 100 may include one of the secondary ESD circuits 410 and 450 or the chip 100 may include both of the secondary ESD circuits 410 and 450.

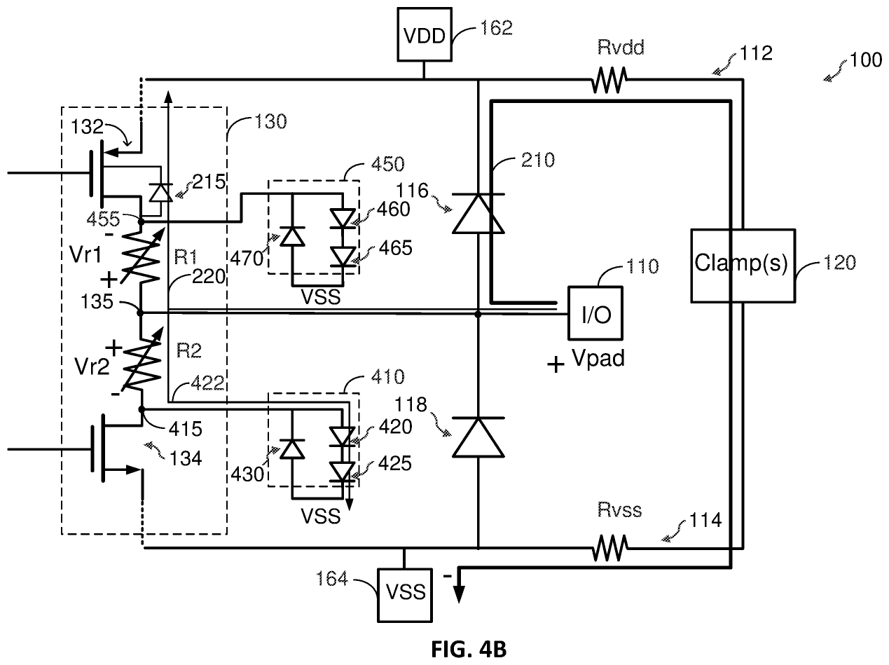

FIG. 5 shows another exemplary implementation of a secondary ESD circuit 510 according to certain aspects. In the example in FIG. 5, the secondary ESD circuit 510 is coupled to a node 515 between the resistor R2 and the driver transistor 134 (e.g., NMOS transistor). The secondary ESD circuit 510 includes a dummy PMOS transistor 520, in which the source and gate of the PMOS transistor 520 are coupled to the VDD bus 112 and the drain of the PMOS transistor 520 is coupled to the node 515. In this example, the PMOS transistor 520 functions as a diode coupled in series with the resistor R2.

During a negative CDM ESD event, the pad voltage Vpad rises above the voltage of the VDD bus 112. Since the drain of the PMOS transistor 520 is coupled to the I/O pad 110 via resistor R2 and the gate of the PMOS transistor 520 is coupled to the VDD bus 112, the drain is at a higher potential than the gate. When the potential difference between the drain and gate exceeds the threshold voltage of the PMOS transistor 520, the PMOS transistor 520 turns on and provides a secondary current path 522 from node 515 to the VDD bus 112. The current flowing through the secondary current path 522 flows through the resistor R2, producing a voltage drop Vr2 across the resistor R2. The voltage drop Vr2 across the resistor R2 lowers the voltage seen at the drain of the driver transistor 134 to Vpad minus Vr2, thereby enhancing the ESD protection of the driver transistor 134.

The secondary ESD circuit 510 may also include a dummy NMOS transistor 530, in which the source and gate of the NMOS transistor 530 are coupled to the VSS bus 114 and the drain of the NMOS transistor 530 is coupled to the node 515. In this example, the NMOS transistor 530 functions as a diode coupled in series with the resistor R2. In this example, the NMOS transistor 530 is configured to provide a secondary current path from the VSS bus 114 to the resistor R2 (e.g., during a positive CDM ESD event).

It is to be appreciated that the dummy PMOS transistor 520 and the dummy NMOS transistor 530 can exist independently. For example, the secondary ESD circuit 510 may include the dummy PMOS transistor 520, but not the dummy NMOS transistor 530. In another example, the secondary ESD circuit 510 may include the dummy NMOS transistor 530, but not the dummy PMOS transistor 520. In another example, the secondary ESD circuit 510 may include both the dummy PMOS transistor 520 and the dummy NMOS transistor 530.

In some implementations, the chip 100 may also include another secondary ESD circuit 550 coupled to a node 555 between the resistor R1 and the driver transistor 132. The secondary ESD circuit 550 includes a dummy PMOS transistor 560, in which the source and gate of the PMOS transistor 560 are coupled to the VDD bus 112 and the drain of the PMOS transistor 560 is coupled to the node 555. In this example, the PMOS transistor 560 functions as a diode coupled in series with the resistor R1.

During a negative CDM ESD event, the pad voltage Vpad rises above the voltage of the VDD bus 112. Since the drain of the PMOS transistor 560 is coupled to the I/O pad 110 via resistor R1 and the gate of the PMOS transistor 560 is coupled to the VDD bus 112, the drain is at a higher potential than the gate. When the potential difference between the drain and gate exceeds the threshold voltage of the PMOS transistor 560, the PMOS transistor 560 turns on and provides a secondary current path from node 555 to the VDD bus 112. Because the PMOS transistor 560 is coupled in series with the resistor R1, the current flowing through the secondary current path flows through the resistor R1. This current may be in addition to the current flowing through the resistor R1 to the drain-body diode 215. In this example, the additional secondary current flow provided by the PMOS transistor 560 increases the voltage drop Vr1 across the resistor R1, which further lowers the voltage seen at the drain of the driver transistor 132. It is to be appreciated that the dummy PMOS transistor 560 may also be used in cases where the drain-body diode 215 is not present.

The secondary ESD circuit 550 may also include a dummy NMOS transistor 570, in which the source and gate of the NMOS transistor 570 are coupled to the VSS bus 114 and the drain of the NMOS transistor 570 is coupled to the node 555. In this example, the NMOS transistor 570 functions as a diode coupled in series with the resistor R1. In this example, the NMOS transistor 570 is configured to provide a secondary current path from the VSS bus 114 to the resistor R1 (e.g., during a positive CDM ESD event).

It is to be appreciated that the dummy PMOS transistor 560 and the dummy NMOS transistor 570 can exist independently. For example, the secondary ESD circuit 550 may include the dummy PMOS transistor 560, but not the dummy NMOS transistor 570. In another example, the secondary ESD circuit 550 may include the dummy NMOS transistor 570, but not the dummy PMOS transistor 560. In another example, the secondary ESD circuit 550 may include both the dummy PMOS transistor 560 and the dummy NMOS transistor 570.

It is also to be appreciated that the secondary ESD circuits 510 and 550 can exist independently. For example, the chip 100 may include one of the secondary ESD circuits 510 and 550 or the chip may include both of the secondary ESD circuits 510 and 550.

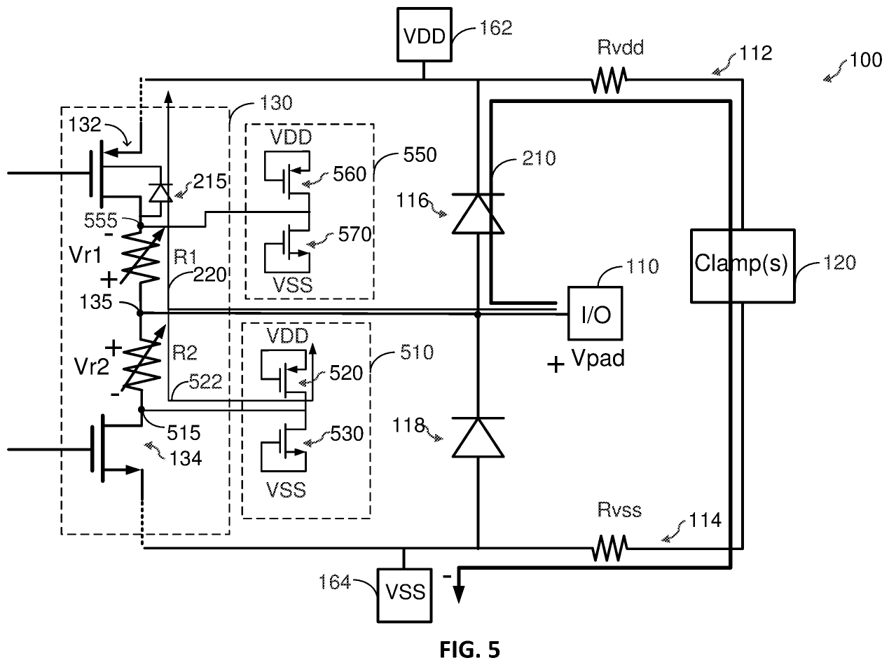

FIG. 6 shows another exemplary implementation of a secondary ESD circuit 610 according to certain aspects. In the example in FIG. 6, the secondary ESD circuit 610 is coupled to a node 615 between the resistor R2 and the driver transistor 134 (e.g., NMOS transistor). The secondary ESD circuit 610 includes a clamp device including a clamp transistor 630 and a trigger device 620 (e.g., RC trigger device). The clamp transistor 630 is coupled between the node 615 and the VSS bus 114. The trigger device 620 is configured to turn off the clamp transistor 630 during normal operation. The trigger device 620 is configured to turn on the clamp transistor 630 during an ESD event (e.g., negative CDM ESD event) to provide a secondary current path 624.

In the example in FIG. 6, the clamp transistor 630 is implemented with an NMOS transistor, in which the drain of the NMOS transistor is coupled to the node 615, the source of the NMOS transistor is coupled to the VSS bus 114, and the gate of the NMOS transistor is coupled to an output 622 of the trigger device 620. In this example, the trigger device 620 turns on the clamp transistor 630 by applying a voltage on the gate of the clamp transistor 630 exceeding the threshold voltage of the clamp transistor 630. It is to be appreciated that the clamp transistor 630 is not limited to an NMOS transistor and may be implemented with another type of transistor.

During a negative CDM ESD event, the trigger device 620 turns on the clamp transistor 630 providing the secondary current path 624 from node 615 to the VSS bus 114. The current flowing through the secondary current path flows through the resistor R2, producing a voltage drop Vr2 across the resistor R2. The voltage drop Vr2 across the resistor R2 lowers the voltage seen at the drain of the driver transistor 134 to Vpad minus Vr2, thereby enhancing the ESD protection of the driver transistor 134.

In some implementations, the chip 100 may also include another secondary ESD circuit 650 coupled to a node 655 between the resistor R1 and the driver transistor 132. The secondary ESD circuit 650 includes a clamp device including a clamp transistor 670 and a trigger device 660 (e.g., RC trigger device). The clamp transistor 670 is coupled between the node 655 and the VSS bus 114. The trigger device 660 is configured to turn off the clamp transistor 670 during normal operation. The trigger device 660 is configured to turn on the clamp transistor 670 during an ESD event (e.g., negative CDM ESD event) to provide a secondary current path.

In the example in FIG. 6, the clamp transistor 670 is implemented with an NMOS transistor, in which the drain of the NMOS transistor is coupled to the node 655, the source of the NMOS transistor is coupled to the VSS bus 114, and the gate of the NMOS transistor is coupled to an output 662 of the trigger device 660. It is to be appreciated that the clamp transistor 670 is not limited to an NMOS transistor and may be implemented with another type of transistor.

During a negative CDM ESD event, the trigger device 660 turns on the clamp transistor 670 providing a secondary current path from node 655 to the VSS bus 114. Because the clamp transistor 670 is coupled in series with the resistor R1, the current flowing through the secondary current path flows through the resistor R1. This current may be in addition to the current flowing through the resistor R1 to the drain-body diode 215. In this example, the additional secondary current flow provided by the clamp transistor 670 increases the voltage drop Vr1 across the resistor R1, which further lowers the voltage seen at the drain of the driver transistor 132. It is to be appreciated that the clamp transistor 670 may also be used in cases where the drain-body diode 215 is not present.

It is also to be appreciated that the secondary ESD circuits 610 and 650 can exist independently. For example, the chip 100 may include one of the secondary ESD circuits 610 and 650 or the chip 100 may include both of the secondary ESD circuits 610 and 650.

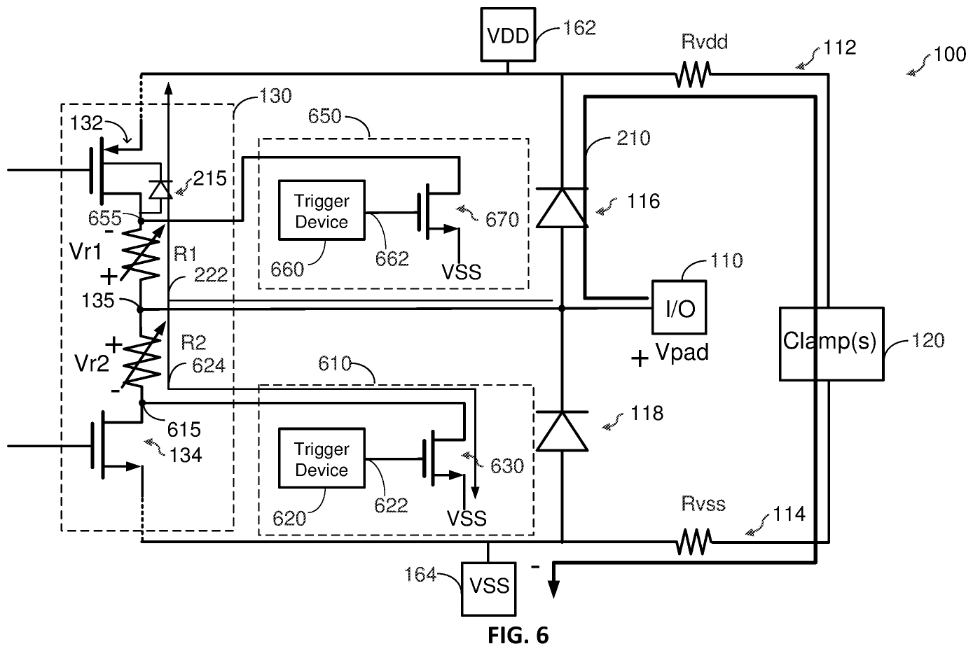

In some implementations, the clamp transistors 630 and 670 may share a trigger device. In this regard, FIG. 7 shows an example in which the clamp transistors 630 and 670 share a trigger device 720. The output 722 of the trigger device 720 is coupled to the gates of the clamp transistors 630 and 670. In the example shown in FIG. 7, each of the clamp transistors 630 and 670 is implemented with an NMOS transistor. However, it is to be appreciated that the present disclosure is not limited to this example and that the clamp transistors 630 and 670 may be implemented with other types of transistors.

During normal operation, the trigger device 720 turns off the clamp transistors 630 and 670. Thus, the clamp transistors 630 and 670 are off during normal operation.

During an ESD event, the trigger device 720 turns on the clamp transistor 630, which provides a secondary current path that allows current to flow through the resistor R2. The current flow produces a voltage drop Vr2 across the resistor R2, which lowers the voltage on the drain of the driver transistor 134, as discussed above. During the ESD event, the trigger device 720 also turns on the clamp transistor 670, which provides a secondary current path that allows current to flow through the resistor R1.

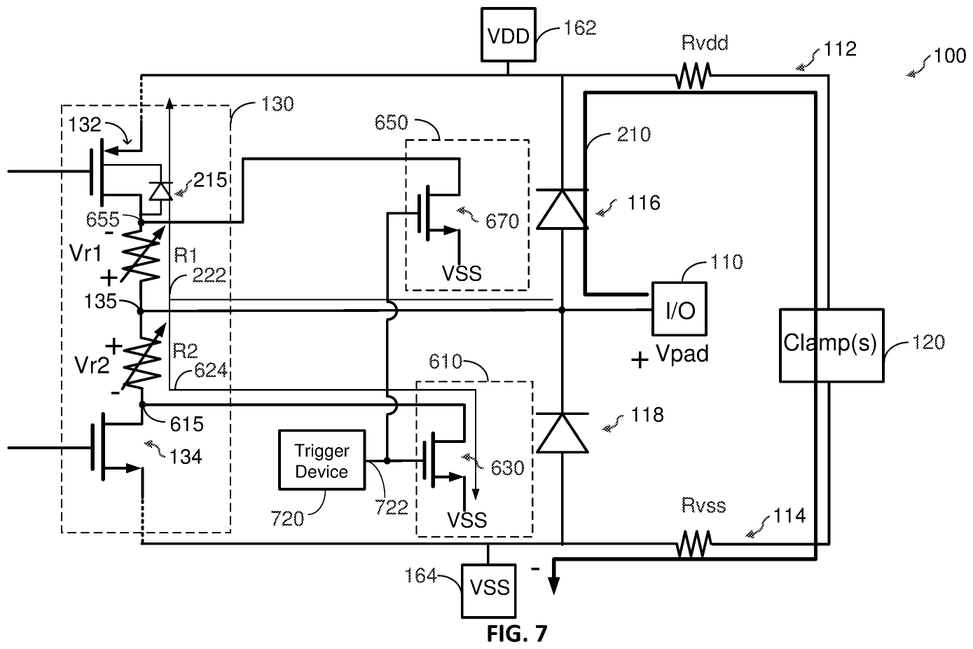

FIG. 8 shows an exemplary implementation of a trigger device 820 according to certain aspects. The exemplary trigger device 820 may be used to implement each of the exemplary trigger devices 620, 660 and 720 discussed above. In this example, the trigger device 820 includes a resistor 832 and a capacitor 834 coupled in series between the VDD bus 112 and the VSS bus 114 to form an RC transient detector 838. The trigger device 820 also includes an inverter 840. The input 842 of the inverter 840 is coupled to a node 836 between the resistor 832 and the capacitor 834. The output 844 of the inverter 840 is coupled to the output 822 of the trigger device 820, which may be coupled to the gates of one or more clamp transistors (e.g., clamp transistors 630 and 670). The inverter 840 may be powered by the VDD bus 112 so that the inverter 840 is turned on when the potential of the VDD bus 112 rises during an ESD event (e.g., negative CDM ESD event).

During normal operation, the capacitor 834 charges to a supply voltage on the VDD bus 112. As a result, the voltage at the input 842 of the inverter 840 is high during normal operation. This causes the output 844 of the inverter 840 to be low, and thus the output 822 of the trigger device 820 to be low. For the example of one or more clamp transistors implemented with one or more NMOS transistors, the low voltage turns off the one or more clamp transistors.

During a negative CDM ESD event, the capacitor 834 does not have time to charge up. This is because the ESD event is a transient event having a shorter time duration than the RC time constant of the RC transient detector 838. Thus, the input 842 of the inverter 840 is low. This causes the output 844 of the inverter 840 to be high, and thus the output 822 of the trigger device 820 to be high during the ESD event. For the example of one or more clamp transistors implemented with one or more NMOS transistors, the high voltage turns on the one or more clamp transistors during the ESD event.

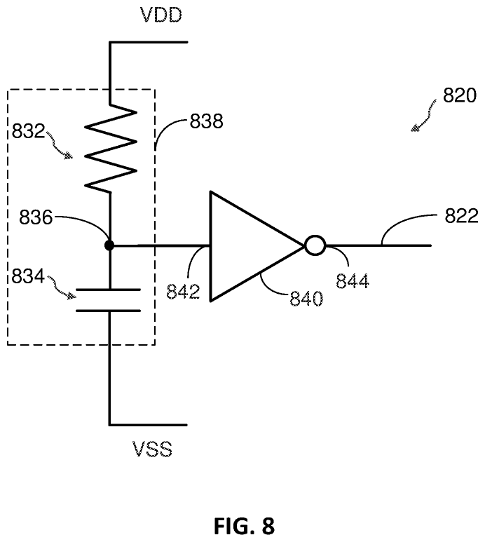

The trigger device 720 may also be used for the clamp device 120 in the primary current path. In this regard, FIG. 9 shows an example in which the output 722 of the trigger device 720 is coupled to the gate of a clamp transistor 910 in the clamp device 120. The trigger device 720 may be implemented with the exemplary trigger device 820 shown in FIG. 8. In the example in FIG. 9, the clamp transistor 910 is implemented with an NMOS transistor. However, it is to be appreciated that the present disclosure is not limited to this example and that the clamp transistor 910 may be implemented with another type of transistor.

During normal operation, the trigger device 720 turns off the clamp transistor 910. During an ESD event, the trigger device 720 turns on the clamp transistor 910, which provides a current path between the VDD bus 112 and the VSS bus 114.

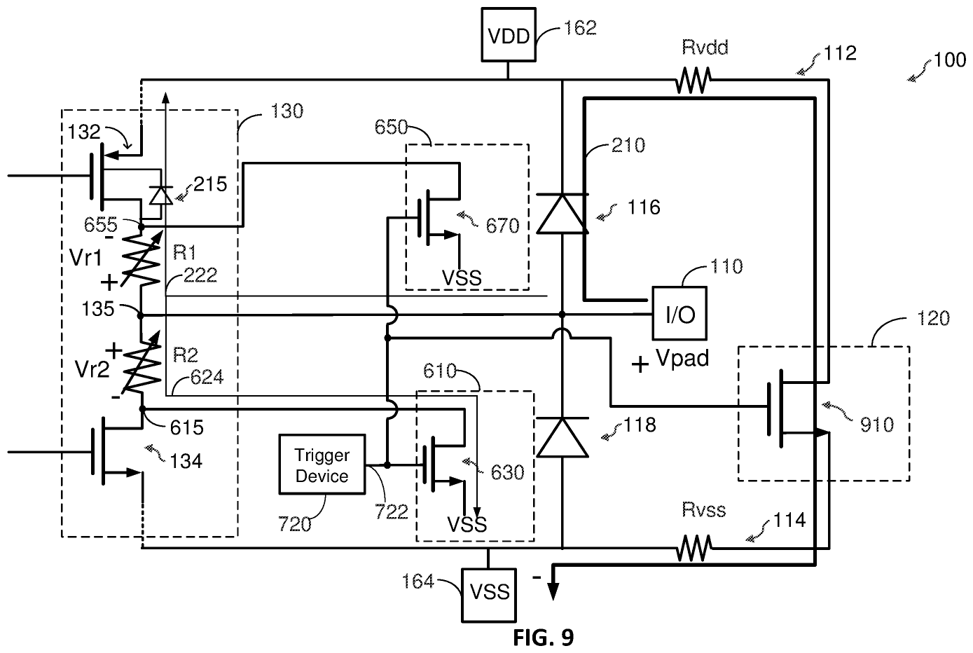

In certain aspects, ESD protection may be incorporated into the driver 130 in which one or more driver transistors (e.g., transistor 132) are turned on during an ESD event. In this regard, FIG. 10 shows an example in which ESD protection is incorporated into the driver 130. In this example, an ESD protection circuit includes a trigger device 1020 (e.g., RC trigger device) and a pass circuit 1040. The trigger device 1020 may be implemented with the exemplary trigger device 820 shown in FIG. 8. However, it is to be appreciated that the trigger device 1020 is not limited to this implementation.

The pass circuit 1040 has a first input 1042, a second input 1044, and an output 1046. In the example in FIG. 10, the first input 1042 is coupled to the output 1022 of the trigger device 1020 and the output 1046 is coupled to the gate of transistor 134. As discussed further below, the pass circuit 1040 couples the trigger device 1020 to the gate of transistor 134 to enable the trigger device 1020 to turn on the transistor 134 during an ESD event.

During normal operation, the second input 1044 of the pass circuit 1040 is configured to receive a drive signal for driving the gate of the transistor 134. The drive signal may carry high-speed data to be transmitted by the driver 130 during normal operation. In some implementations, the driver signal may be provided by a predriver circuit 1030 coupled to the second input 1044. The pass circuit 1040 passes the drive signal to the gate of the transistor 134 during normal operation. During an ESD event, the pass circuit 1040 passes the trigger signal from the trigger device 1020 to the gate of the transistor 134 where the trigger signal is a signal that turns on the transistor 134. Thus, the pass circuit 1040 allows the transistor 134 in the driver 130 to be used for ESD protection while preserving the normal functionality of the transistor 134.

In the example in FIG. 10, the pass circuit 1040 is implemented with an OR gate 1050. In this example, the output 1022 of the trigger device 1020 is low during normal operation. As a result, the OR gate 1050 passes the drive signal to the gate of the transistor 134 during normal operation. During an ESD event, the trigger output 1022 is high. This causes the output of the OR gate 1050 to be high, which turns on transistor 134. Thus, the OR gate 1050 allows the trigger device 1020 to turn on transistor 134 during the ESD event while passing the driving signal to the gate of the transistor 134 during normal operation. It is to be appreciated that the pass circuit 1040 is not limited to an OR gate and may be implemented with another type of logic gate or a combination of logic gates.

During a negative CDM ESD event, the trigger device 1020 turns on the transistor 134 providing a secondary current path 1052 from the resistor R2 to the VSS bus 114. The current flowing through the secondary current path 1052 flows through the resistor R2, producing a voltage drop Vr2 across the resistor R2. The voltage drop Vr2 across the resistor R2 lowers the voltage seen at the drain of transistor 134 to Vpad minus Vr2, thereby enhancing the ESD protection of transistor 134.

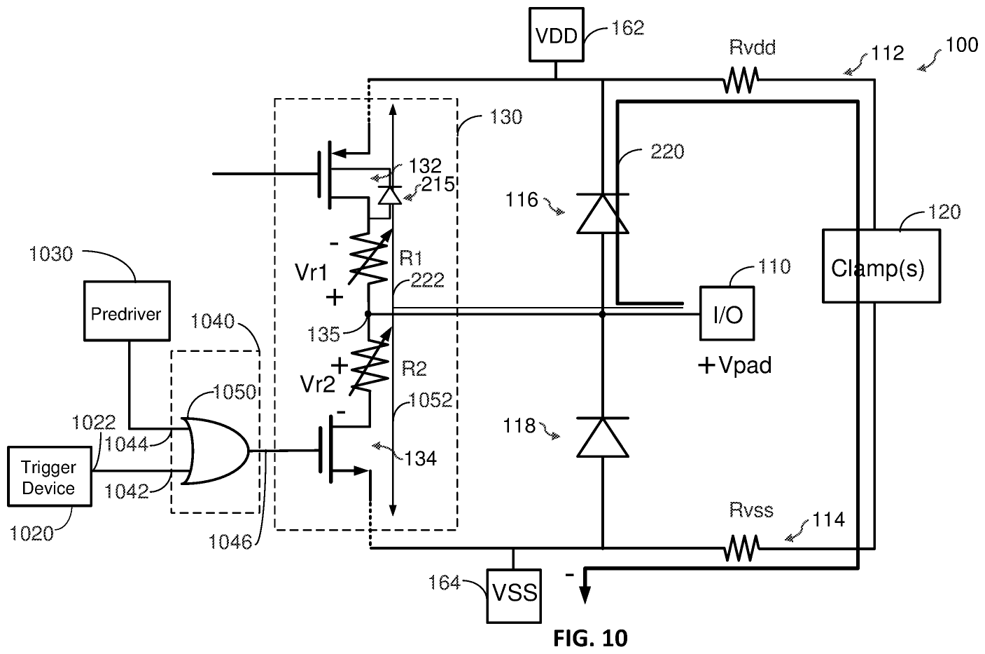

FIG. 11 shows another example in which ESD protection is incorporated into the driver 130. In this example, an ESD protection circuit uses both driver transistors 134 and 132 for ESD protection, as discussed further below. The ESD protection circuit includes a trigger device 1120 (e.g., RC trigger device), which may be implemented with the exemplary trigger device 820 shown in FIG. 8. However, it is to be appreciated that the trigger device 1120 is not limited to this implementation. In the example in FIG. 11, the trigger device 1120 has a first output 1122 coupled to the output 844 of inverter 840. The trigger device 1120 also includes a second inverter 1130 with an input 1132 coupled to the output 844 of inverter 840 and an output 1134 coupled to the second output 1124 of the trigger device 1120.

The ESD protection circuit also includes the pass circuit 1040 discussed above. In the example in FIG. 11, the first input 1042 of the pass circuit 1040 is coupled to the first output 1122 of the trigger device 1120, the second input 1044 of the pass circuit 1040 is configured to receive the drive signal during normal operation, and the output 1046 of the pass circuit 1040 is coupled to the gate of transistor 134. In the example in FIG. 11, the pass circuit 1040 is implemented with an OR gate 1050. However, it is to be appreciated that the pass circuit 1040 may also be implemented with other logic gates.

The ESD protection circuit also includes a second pass circuit 1140 having a first input 1142, a second input 1144, and an output 1148. The first input 1142 of the pass circuit 1140 is coupled to the second output 1124 of the trigger device 1120, the second input 1144 of the pass circuit 1140 is configured to receive the drive signal during normal operation, and the output 1148 of the pass circuit 1140 is coupled to the gate of transistor 132. In the example in FIG. 11, the pass circuit 1140 is implemented with an AND gate 1150. However, it is to be appreciated that the pass circuit 1140 may also be implemented with other logic gates.

During normal operation, the second inputs 1044 and 1144 of the pass circuits 1040 and 1140 receive a drive signal. The drive signal may carry high-speed data to be transmitted by the driver 130 during normal operation. In some implementations, the driver signal may be provided by the predriver circuit 1030, which may be coupled to the second inputs 1044 and 1144. The pass circuits 1040 and 1140 couple the drive signal to the gates of transistors 134 and 132, respectively, during normal operation. Thus, the pass circuits 1040 and 1140 allow the transistors 132 and 134 in the driver 130 to be used for ESD protection while preserving the normal functionalities of these transistors 132 and 134.

In the example in FIG. 11, the first pass circuit 1040 includes the OR gate 1050 discussed above. The inputs of the OR gate 1050 are coupled to the first output 1122 of the trigger device 1120 and the drive signal, and the output of the OR gate 1050 is coupled to the gate of transistor 134. In this example, the first output 1122 of the trigger device 1120 is low during normal operation. As a result, the OR gate 1050 passes the drive signal to the gate of the transistor 134 during normal operation. During an ESD event, the first output 1122 of the trigger device 1120 is high. This causes the output of the OR gate 1050 to be high, which turns on transistor 134. Thus, the OR gate 1050 allows the trigger device 1120 to turn on transistor 134 during the ESD event.

In the example in FIG. 11, the pass circuit 1140 includes the AND gate 1150. The inputs of the AND gate 1150 are coupled to the second output 1124 of the trigger device 1120 and the drive signal, and the output of the AND gate 1150 is coupled to the gate of transistor 132. In this example, the second output 1124 of the trigger device 1120 is high during normal operation. This causes the AND gate 1150 to pass the drive signal to the gate of the transistor 132 during normal operation. During an ESD event, the second output 1124 of the trigger device 1120 is low. This causes the output of the AND gate 1150 to be low, which turns on transistor 132 since transistor 132 is implemented with a PMOS transistor in the example shown in FIG. 11.

Thus, during a negative CDM ESD event, the trigger device 1120 turns on the transistors 132 and 134. The turning on of transistor 132 provides a secondary current path 1152. The current flowing through the secondary current path 1152 passes through resistor R1, producing a voltage drop Vr1 across the resistor R1, which lowers the voltage seen at transistor 132 and hence lowers the voltage stress on transistor 132. The turning on of transistor 134 provides a secondary current path 1052. The current flowing through the secondary current path 1052 passes through resistor R2, producing a voltage drop Vr2 across the resistor R2, which lowers the voltage seen at transistor 134 and hence lowers the voltage stress on transistor 134.

It is to be appreciated that the pass circuit 1140 is not limited to the exemplary implementation in FIG. 11. For example, in implementations in which transistor 132 is an NMOS transistor, the AND gate 1150 may be replaced with an OR gate.

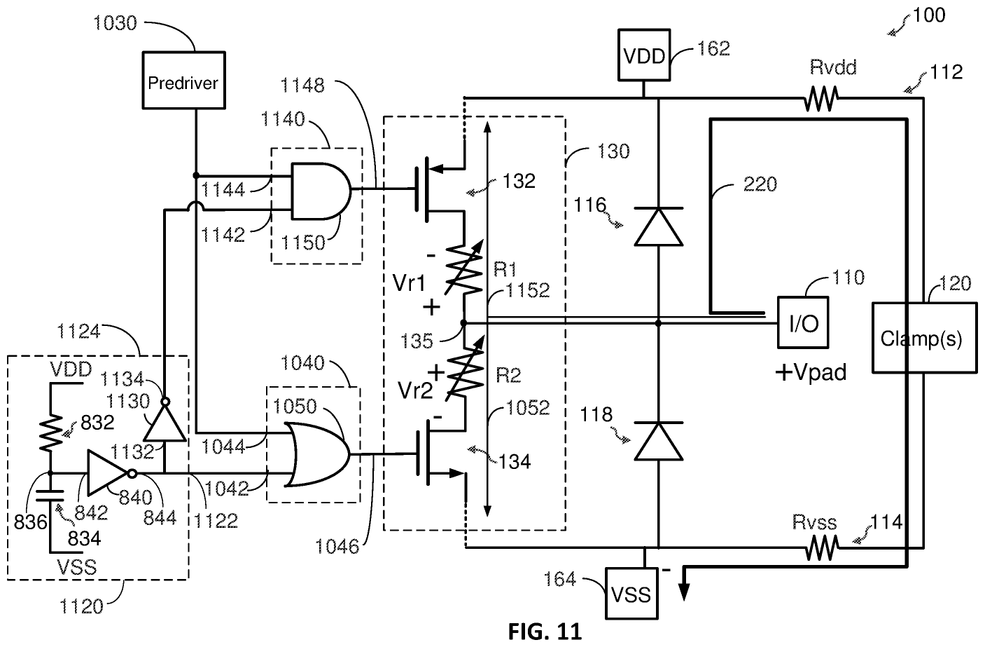

In certain aspects, ESD protection may be incorporated into impedance matching networks. The impedance matching networks may be on the driver side and/or receiver side. In this regard, FIG. 12 shows an example in which ESD protection is incorporated into impedance matching networks according to certain aspects. In this example, the chip 1200 includes a first pad 1210, a second pad 1215, a first impedance matching network 1230, a second impedance matching network 1240, and a transistor 1260 (e.g., NMOS transistor). The first impedance matching network 1230 is coupled between the first pad 1210 and the transistor 1260 and the second impedance matching network 1240 is coupled between the second pad 1215 and the transistor 1260. The impedance matching networks 1230 and 1240 may be used, for example, for impedance matching for a differential receiver, a driver, and/or another interface circuit. The transistor 1260 is coupled between each impedance matching network and a vssa bus.

The first impedance matching network 1230 includes multiple slices 1232-1 to 1232-3 where each slice includes a respective resistor 1234-1 to 1234-3 and a respective transistor 1236-1 to 1236-3 (e.g., NMOS transistor) coupled in series. Although three slices are shown in the example in FIG. 12, it is to be appreciated that the first impedance matching network 1230 may include any number of slices. During normal operation, the impedance of the impedance matching network 1230 is controlled by controlling the number of slices that are on and off. A slice is turned on by turning on the respective transistor and turned off by turning off the respective transistor.

The second impedance matching network 1240 includes multiple slices 1242-1 to 1242-3 where each slice includes a respective resistor 1244-1 to 1244-3 and a respective transistor 1246-1 to 1246-3 (e.g., NMOS transistor) coupled in series. During normal operation, the impedance of the impedance matching network 1240 is controlled by controlling the number of slices that are on and off.

The transistor 1260 is used to switch the impedance matching networks to ground or another polarity directly. In some implementations, the transistor 1260 may be omitted with the sources of the transistors 1236-1 to 1236-3 and 1246-1 to 1246-3 going directly to the vssa bus.

The ESD protection circuit includes ESD diodes 1212 and 1217, a trigger device 1220 and a clamp transistor 1222. The clamp transistor 1222 (e.g., NMOS) is coupled between vcca bus and vssa bus. The clamp transistor 1222 is triggered (i.e., turned on) by the trigger device 1220 during an ESD event to provide a discharge current path between vcca and vssa. In the example shown in FIG. 12, the trigger device 1220 is implemented with an RC trigger device including a resistor 1226 and a capacitor 1228 coupled in series between the vcca bus and the vssa bus, in which the output 1227 of the trigger device 1220 is located at the node 1225 between the resistor 1226 and the capacitor 1228. However, it is to be appreciated that the trigger device 1220 is not limited to this example.

The output 1227 of the trigger device 1220 is coupled to the gates of the transistors 1236-1 to 1236-3 in the first impedance matching network 1230 via pass circuit 1252 (e.g., NAND gate), the gates of the transistors 1246-1 to 1246-3 in the second impedance matching network 1240 via pass circuit 1256 (NAND gate), and the gate of transistor 1260 via pass circuit 1254 (e.g., NAND gate). The pass circuits 1252, 1254 and 1256 are configured to pass control signals to the transistors during normal operation. In this example, during an ESD event, the trigger signal for the transistors in the impedance matching networks 1230 and 1240 and transistor 1260 are taken before the inverter 1224. In this example, the pass circuits 1252, 1254 and 1256 invert the trigger signal from the trigger device 1220, thereby performing the inverting function of the inverter 1224. In other implementations, the trigger signal for the pass circuits 1252, 1254 and 1256 may be taken after the inverter 1224 (e.g., in implementations where the pass circuits 1252, 1254 and 1256 are non-inverting). Thus, whether the trigger signal is taken before or after the inverter 1224 is implementation dependent.

During an ESD event, the trigger device 1220 turns on the transistors in the impedance matching networks 1230 and 1240 and transistor 1260. This creates secondary current paths from the pad 1210 to vssa through the resistors 1234-1 to 1234-3 in the first impedance matching network 1230, and creates secondary current paths from the pad 1215 to vssa through the resistors 1244-1 to 1244-3 in the second impedance matching network 1240. The currents flowing through the resistors 1234-1 to 1234-3 produce IR voltage drops that lower the voltages seen at the transistors 1236-1 to 1236-3 during the ESD event. The currents flowing through the resistors 1244-1 to 1244-3 produce IR voltage drops that lower the voltages seen at the transistors 1246-1 to 1246-3 during the ESD event. Hence, the voltage stress on these transistors is reduced.

Thus, examples have been presented in which ESD protection can be incorporated into drivers and impedance matching networks to take advantage of existing circuits. However, it is to be appreciated that this technique is not limited to drivers and impedance matching networks and that ESD protection may be incorporated into other types of existing interface circuits that are coupled to an I/O pad to take advantage of existing circuits.

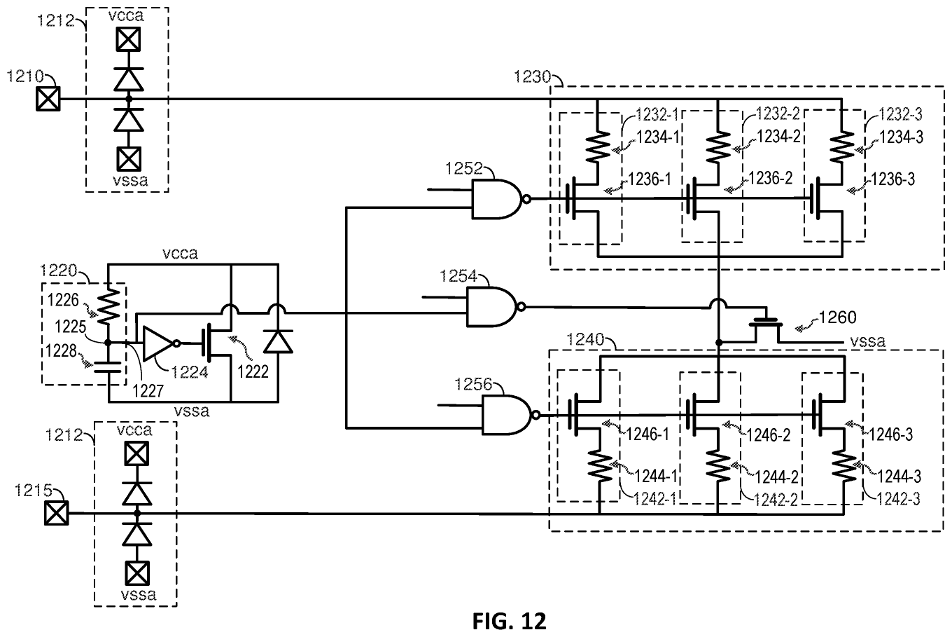

FIG. 13 conceptually generalizes the exemplary ESD circuit schemes discussed above according to various aspects of the present disclosure. Exemplary ESD circuit schemes according to certain aspects involve creating one or more secondary current paths that creates one or more voltage drops across one or more resistors (e.g., resistor R1 and/or resistor R2). The one or more voltage drops lower the voltage seen by one or more protected transistors (e.g., transistor 132 and/or transistor 134). Instead of the full pad voltage Vpad, a protected transistor sees a voltage of Vpad minus the voltage drop across the resistor coupled in series with the protected transistor.

For example, a secondary current path may be created by a secondary ESD circuit (e.g., any one or more of the exemplary secondary ESD circuits discussed above). In this regard, FIG. 13 shows an example of a secondary ESD circuit 1310 coupled to a node between resistor R2 and transistor 134 and configured to create a secondary current path through R2. The secondary ESD circuit 1310 may be implemented with any one of the exemplary secondary ESD circuits 310, 410, 510, and 610. However, the secondary ESD circuit 1310 is not limited to these examples. FIG. 13 also shows an example of another secondary ESD circuit 1350 coupled to a node between resistor R1 and transistor 132 and configured to create a secondary current path through R1. The secondary ESD circuit 1350 may be implemented with any one of the exemplary secondary ESD circuits 350, 450, 550, and 650. However, the secondary ESD circuit 1350 is not limited to these examples.

A secondary current path may also be created by turning on an existing transistor (e.g., transistor 132 or 134) in an interface circuit (e.g., driver 130) during an ESD event (e.g., using trigger device 1020 or 1120). A secondary path can also come from a parasitic element drain-body diode 215) of a driver device (e.g., driver transistor 132), By taking advantage of one or more pre-existing resistors (e.g., resistor R1 and/or resistor R2) and creating one or more secondary current paths through the one or more pre-existing resistors, ESD protection schemes according to various aspects provide enhanced ESD robustness with minimal impact on the performance of the M.

Exemplary ESD circuit schemes according to aspects of the present disclosure are also applicable to cases where one or more protected transistors (e.g., transistor 132 and 134) are coupled to the pad through a parasitic resistor (e.g., due to parasitic routing resistance).

Exemplary ESD circuit schemes according to aspects of the present disclosure are also applicable to cases where the resistors R1 and R2 are not present. In these cases, a secondary current path that is created by a secondary ESD circuit or by turning on an existing transistor (e.g., transistor 132 or 134) reduces the voltage on the pad Vpad. This is because the current flowing the secondary current path reduces the amount of current flowing though the primary current path 210, which reduces the voltage drops (e.g., IR voltage drops) in the primary current path 210 and hence reduces the pad voltage Vpad. In these cases, enhanced ESD protection is provided by splitting the current between the primary current path and the secondary current path and the resulting total voltage reduction on the pad 110.

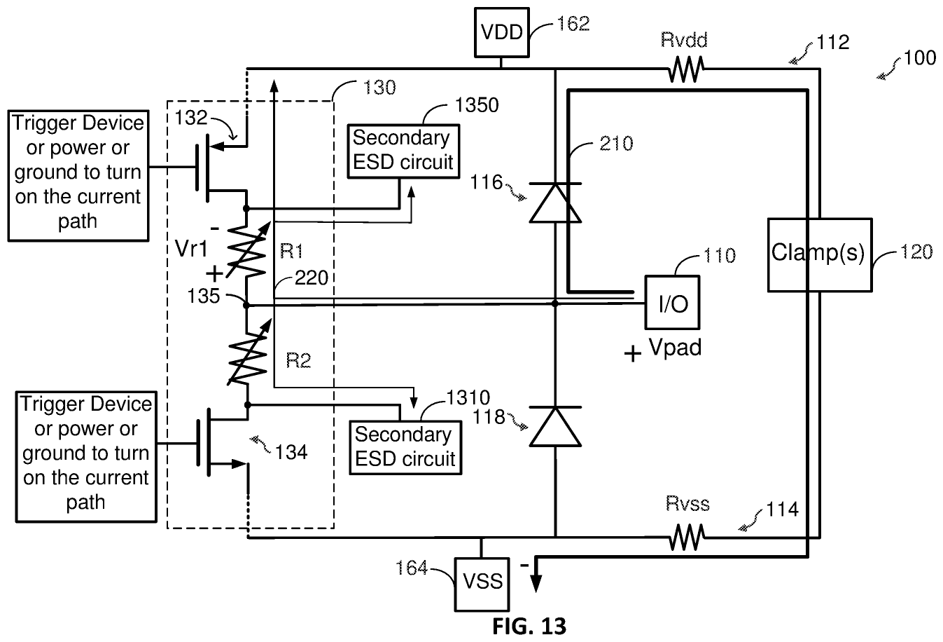

It is to be appreciated that the exemplary ESD protection schemes discussed above may also apply to cases where transistors (e.g., driver transistors 132 and 134) share a common resistor. In this regard, FIG. 14 shows an example in which the driver transistors 132 and 134 share a common resistor R. In this example, the resistor R is coupled between the drain of driver transistor 134 and the pad 110. The resistor R is also coupled between the drain of driver transistor 132 and the pad 110.

In this example, a secondary current path created by any of the exemplary ESD protection schemes discussed above causes current to flow through the common resistor R creating a voltage drop Vr across the common resistor R. The voltage drop Vr lowers the voltage seen at the transistors 132 and 134, thereby enhancing ESD protection for these transistors 132 and 134.

The secondary current path may be created by a secondary ESD circuit (e.g., any one or more of the exemplary secondary ESD circuits discussed above). In this case, the secondary ESD circuit may be coupled to node 1405 so that the current flowing through the secondary ESD circuit flows through the resistor R. In this regard, FIG. 14 shows an example of a secondary ESD circuit 1410 coupled to the node 1405. The secondary ESD circuit 1410 may be implemented, with any one or more of the exemplary secondary ESD circuits 310, 350, 410, 450, 510, 550, 610, and 650. However, the secondary ESD circuit 1410 is not limited to these examples.

The secondary current path may also be created by turning on an existing transistor (e.g., transistor 132 and/or transistor 134) during an ESD event. For example, the secondary current path may be created by turning on transistor 134 with a trigger device 1420 coupled to the gate of transistor 134. The trigger device 1420 may be implemented with any of the exemplary trigger devices 820, 1020, and 1120 discussed above, but is not limited to these examples. The trigger device 1420 may be coupled to the gate of transistor 134 via a pass circuit (not shown in FIG. 14) configured to pass a drive signal to transistor 134 during normal operation. The secondary current path may also be created by turning on transistor 132 with a trigger device 1430 coupled to the gate of transistor 132. The trigger device 1430 may be implemented with any of the exemplary trigger devices 820 and 1120 discussed above, but is not limited to these examples. The trigger device 1430 may be coupled to the gate of transistor 132 via a pass circuit (not shown in FIG. 14) configured to pass a drive signal to transistor 132 during normal operation. Examples of pass circuits include, but are not limited to, pass circuits 1040 and 1140. The secondary current path can also come from a parasitic element (e.g., drain-body diode 215) of a driver device (e.g., transistor 132), The secondary current path may be created by any combination of a secondary ESD circuit, turning on one or more existing transistors, and/or parasitic element.

In some cases, the normal operating voltage on the pad 110 can be low and below the turn-on voltage of a diode. For example, in some cases, a low voltage interface (e.g., driver) may have a low voltage swing (e.g., <0.4V). In these cases, ESD protection can be enhanced using a structure with a forward diode from the pad 110 to the VSS bus as opposed to the conventional ESD protection scheme where an up diode 116 is coupled from the pad 110 to the VDD bus. In this structure, the voltage on the pad 110 during an ESD may be much lower than the conventional scheme since the ESD current flows directly from the pad 110 to the VSS bus through the forward diode and has less dependency on bus resistance.

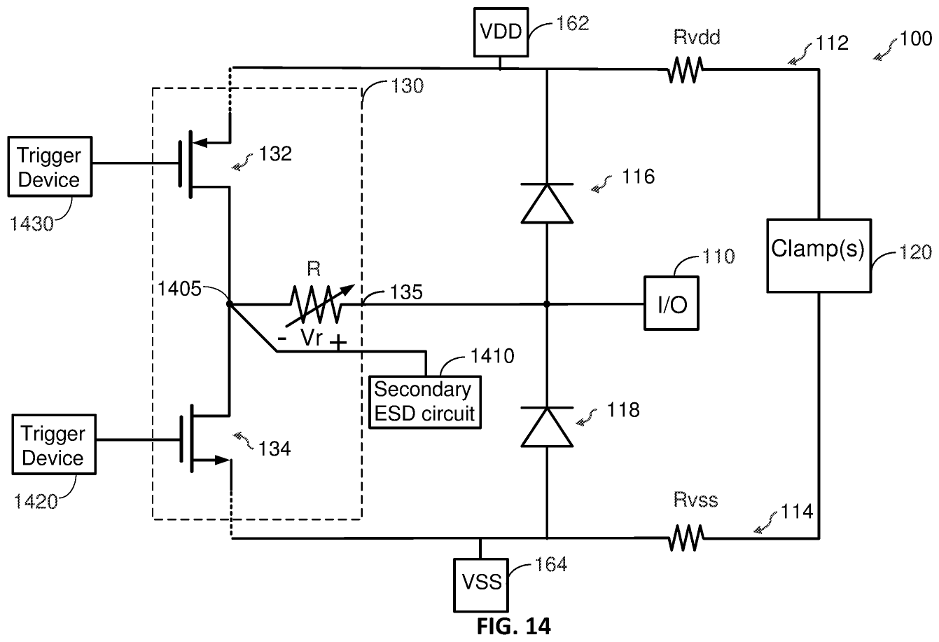

FIG. 15 shows an example of an ESD protection circuit including a first diode 1510 and a second diode 1520 coupled between the pad 110 and the VSS bus according to certain aspects of the present disclosure. The anode of the first diode 1510 is coupled to the pad 110 and the cathode of the first diode 1510 is coupled to the VSS bus. The anode of the second diode 1520 is coupled to the VSS bus and the cathode of the second diode 1520 is coupled to the pad. The exemplary ESD protection circuit shown in FIG. may be used, for example, for low voltage interfaces (e.g., voltage swing <0.4V), which are less likely to unintentionally turn on the diode 1510 during normal operation.

During a negative CDM ESD event, the first diode 1510 turns on and provides a current path 1530 from the pad 110 to the VSS bus. The current flowing through the first diode 1510 lowers the pad voltage Vpad due to reduced elements in the current path 1530 compared with the current path 210 in FIG. 2. The lower pad voltage Vpad reduces the voltage stress on the transistors 132 and 134. The second diode 1520 is configured to provide a current path from the VSS bus to the pad 110 (e.g., during a positive CDM ESD event).

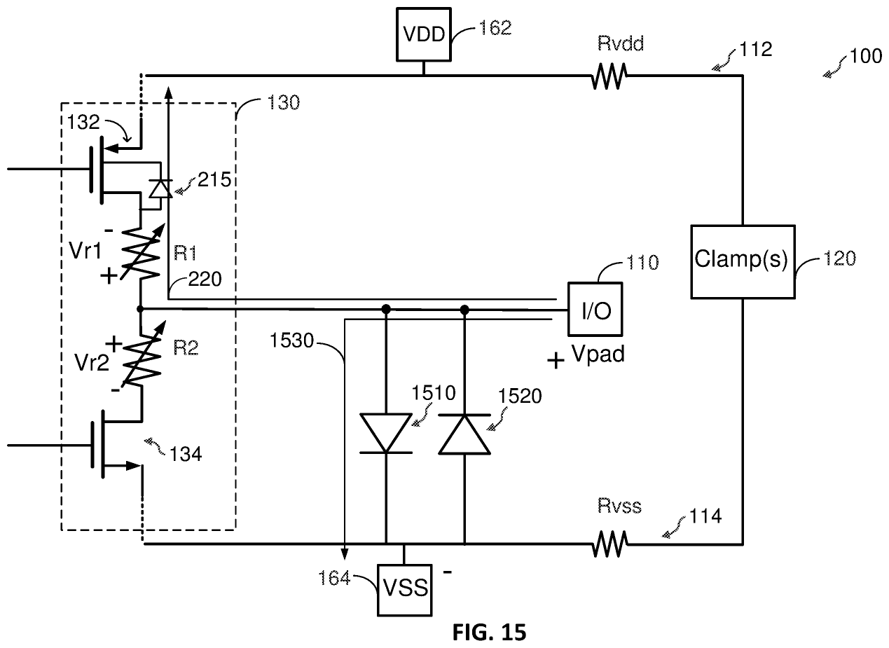

FIG. 16 shows an example in which the ESD protection circuit includes another diode 1515 coupled in series with the first diode 1510. Thus, in this example, the ESD protection circuit includes two stacked diodes between the pad 110 and the VSS bus. The diodes 1510 and 1515 are in the forward direction from the pad 110 to the VSS bus 114 such that the diodes 1510 and 1515 are forward biased when the potential of the pad 110 is higher than the potential of the VSS bus 114. In this example, the stacked diodes 1510 and 1520 turn on to provide the current path 1530 (i.e., discharge path) from the pad 110 to the VSS bus when Vpad exceeds the sum of the turn-on voltages of the diodes 1510 and 1520. The stacked diodes 1510 and 1520 may be used, for example, to prevent the current path 1530 from unintentionally turning on during normal operation of the driver 130 in cases where the turn-on voltage of a single diode is lower than the output voltage swing of the driver 130.

In the example in FIG. 16, the ESD protection circuit also includes another diode 1525 coupled in series with the second diode 1520. The stacked diodes 1520 and 1525 may provide a current path from the VSS bus to the pad 110 (e.g., during a positive CDM ESD event).

It is to be appreciated that, in other implementations, more than two diodes may be coupled in series between the pad 110 and the VSS bus in the forward direction from pad 110 to the VSS bus, and more than two diodes may be coupled in series between the pad 110 and the VSS bus in the forward direction from VSS bus to the pad 110.

In certain aspects, diodes may be laid out on a chip to provide the option of coupling a single forward diode 1510 from the pad 110 to the VSS bus (e.g., illustrated in FIG. 15) or coupling a stack of forward diodes 1510 and 1515 from the pad 110 to the VSS bus using only a metal change. In some extreme corners such as high temperature use case, a single diode (e.g., diode 1510) from the pad 110 to the VSS bus may cause a performance impact on the I/O due to the reduced turn-on voltage of the diode at higher temperatures. In such corners, two diodes may be coupled in series form the pad 110 and the VSS bus by programming the metal routing accordingly. In other corners where a single forward diode can be used with little to no performance impact, the single forward diode may be coupled from the pad 110 to the VSS bus by programming the metal routing accordingly. Thus, the diodes may be laid out such that various ESD protection schemes can be easily programmed with metal only changes. Programming a metal change may be done, for example, by changing one or more masks that define metal routing for the diodes during chip fabrication.

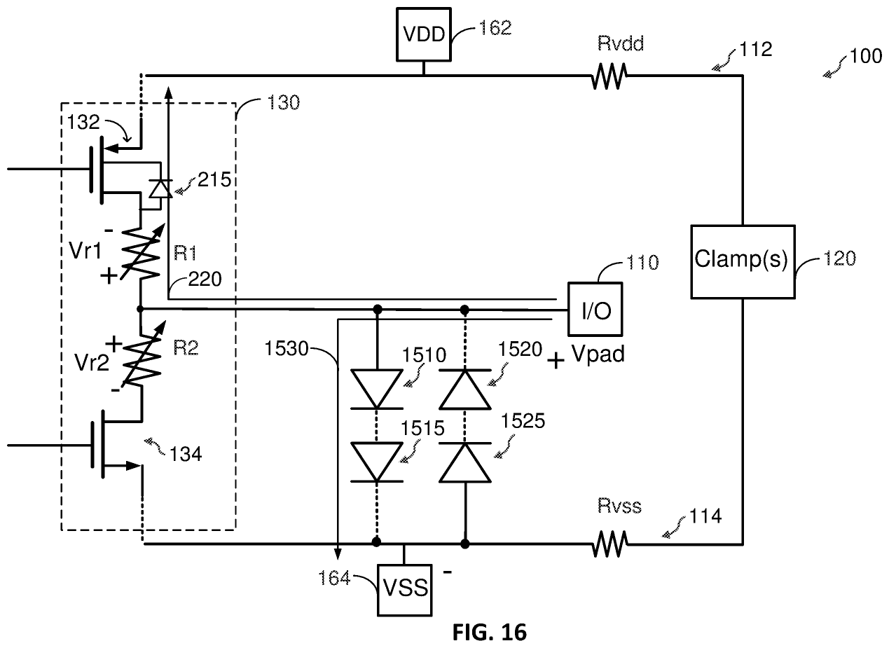

FIG. 17 illustrates a method 1700 of electrostatic discharge (ESD) protection for an interface circuit coupled to a pad according to certain aspects. The interface circuit (e.g., driver 130) includes a transistor (e.g., transistor 132 or 134) and a resistor (e.g., resistor R1 or R2) coupled between the pad (e.g., pad 110) and the transistor.

At block 1710, during an ESD event, a current path is provided between a node and a bus, wherein the node is between the resistor and the transistor. In certain aspects, the current path is provided by one or more of the exemplary secondary ESD circuits 310, 350, 410, 450, 510, 550, 610, and 650. The ESD event may include a charged device model (CDM) event or another type of ESD event. The bus may include a voltage supply bus (e.g., VDD bus) or a ground bus (e.g., VSS bus).

In certain aspects, providing the current path may include forward biasing one or more diodes coupled between the node and the bus. The one or more diodes may include one or more of the diodes 320, 325, 365, 360, 420, 425, 430, 460, 465, and 470.

In certain aspects, the bus includes a voltage supply bus (e.g., VDD bus). In these aspects, the method 1700 may further include detecting the ESD event, and, in response to detecting the ESD event, turning on a clamp device (e.g., clamp device 120) coupled between the voltage supply bus and a ground bus (e.g., VSS bus).

In certain aspects, a clamp transistor (e.g., clamp transistor 630 or 670) is coupled between the node and the bus. In these aspects, providing the current path may include detecting the ESD event, and, in response to detecting the ESD event, turning on the clamp transistor. In one example, detecting the ESD event includes detecting the ESD event using a resistor-capacitor (RC) transient detector (e.g., RC transient detector 838).

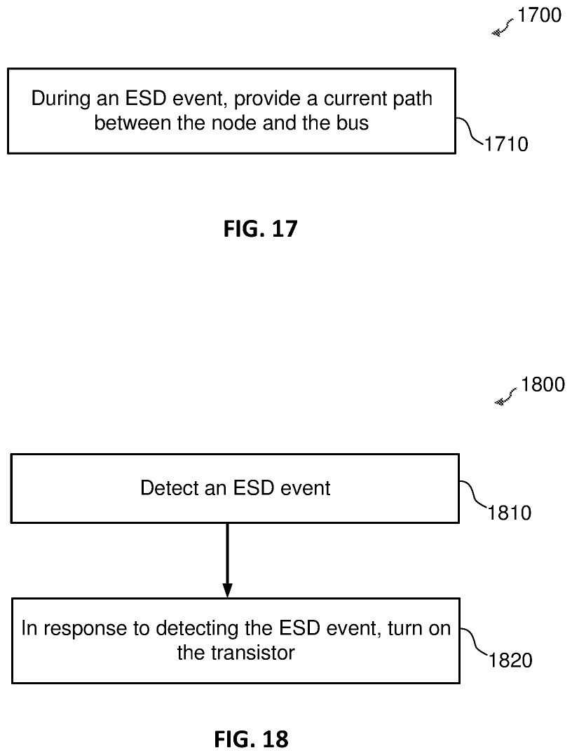

FIG. 18 illustrates a method 1800 of electrostatic discharge (ESD) protection for an interface circuit coupled to a pad according to certain aspects. The interface circuit (e.g., driver 130) includes a transistor (e.g., transistor 132 or 134) and a resistor (e.g., resistor R1 or R2) coupled between the pad (e.g., pad 110) and the transistor.

At block 1810, an ESD event is detected. For example, the ESD detector may be detected by the resistor-capacitor (RC) transient detector 838.

At block 1820, in response to detecting the ESD event, the transistor is turned on. For example, the transistor may be turned on by the trigger device 620, 660, 720, 820, 1020, or 1220.

In certain aspects, the method 1800 may also include, driving a gate of the transistor with a data signal or a control signal. For example, the gate of the transistor may be driven by the predriver circuit 1030 during the normal operation.

In certain aspects, detecting the ESD event may include generating a trigger signal based on the ESD event, and turning on the transistor may include passing the trigger signal to a gate of the transistor. For example, the trigger signal may be generated by the trigger device 620, 660, 720, 820, 1020, or 1220, and the trigger signal may be passed to the gate of the transistor by the pass circuit 1040, 1140, 1252, 1254, or 1256.

In certain aspects, the method 1800 may further include passing a drive signal from a predriver circuit to the gate of the transistor. For example, the drive signal may be passed to the gate of the transistor by the pass circuit 1040, 1140, 1252, 1254, or 1256. The drive signal may include a data signal or a control signal. The pass circuit 1040, 1140, 1252, 1254, or 1256 may include a logic gate including, but not limited to, an OR gate, an AND gate, or a NAND gate.

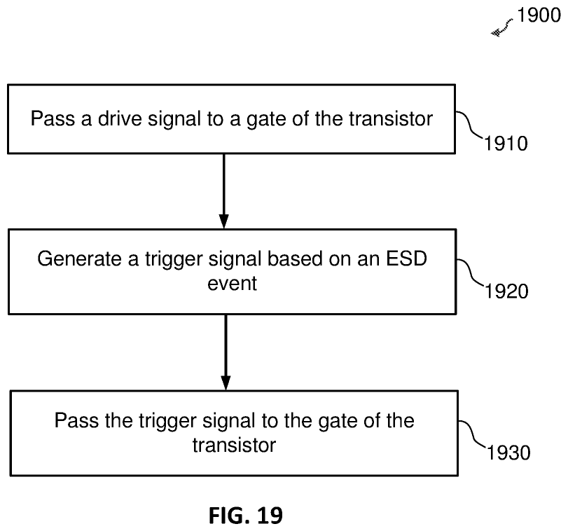

FIG. 19 illustrates a method 1900 of electrostatic discharge (ESD) protection for an interface circuit coupled to a pad according to certain aspects. The interface circuit (e.g., driver 130) includes a transistor (e.g., transistor 132 or 134) coupled to the pad (e.g., pad 110).

At block 1910, a drive signal is passed to a gate of the transistor. For example, the driver signal may be passed to the gate of the transistor by the pass circuit 1040, 1140, 1252, 1254, or 1256. The drive signal may include a data signal or a control signal. The drive signal is passed to the gate during normal operation of the interface circuit.

At block 1920, a trigger signal is generated based on an ESD event. For example, the trigger signal may be generated by the trigger device 620, 660, 720, 820, 1020, or 1220.

At block 1830, the trigger signal is passed to the gate of the transistor. For example, the trigger signal may be passed to the gate of the transistor by the pass circuit 1040, 1140, 1252, 1254, or 1256.

In certain aspects, passing the drive signal to the gate of the transistor may include passing the drive signal to the gate of the transistor using a logic gate. The logic gate may include an OR gate, an AND gate, or a NAND gate.

Implementation examples are described in the following numbered clauses:

1. A chip, comprising:
a pad;
an interface circuit coupled to the pad, wherein the interface circuit includes:
   a transistor; and
   a resistor coupled between the pad and the transistor; and
an electrostatic discharge (ESD) circuit coupled to a node between the resistor and the transistor, wherein the ESD circuit is configured to provide a current path between the node and a first bus during an ESD event.

2. The chip of clause 1, wherein the interface circuit comprises a driver.

3. The chip of clause 1 or 2, wherein the transistor comprises an NMOS transistor.

4. The chip of any one of clauses 1 to 3, wherein the ESD circuit comprises a diode coupled between the node and the first bus.

5. The chip of clause 4, wherein the first bus comprises a voltage supply bus.

6. The chip of clause 4 or 5, further comprising a clamp device coupled between the first bus and a second bus.

7. The chip of clause 6, wherein the first bus comprises a voltage supply bus and the second bus comprises a ground bus.

8. The chip of any one of clauses 1 to 3, wherein the ESD circuit comprises one or more diodes coupled between the node and the first bus.

9. The chip of clause 8, wherein the first bus comprises a ground bus.

10. The chip of clause 8 or 9, wherein the one or more diodes are in a forward direction from the node to the first bus.

11. The chip of any one of clauses 8 to 10, wherein the one or more diodes comprise a stack of two or more diodes.

12. The chip of any one of clauses 1 to 3, wherein the ESD circuit comprises a dummy transistor, a source and a gate of the dummy transistor are coupled to the first bus, and a drain of the dummy transistor is coupled to the node.

13. The chip of clause 12, wherein the dummy transistor comprises a PMOS transistor and the first bus comprises a voltage supply bus.

14. The chip of clause 12, wherein the dummy transistor comprises an NMOS transistor and the first bus comprises a ground bus.

15. The chip of any one of clauses 1 to 3, wherein the ESD circuit comprises:
a clamp transistor coupled between the node and the first bus; and
a trigger device coupled to a gate of the clamp transistor.

16. The chip of clause 15, wherein the trigger device comprises a resistor-capacitor (RC) transient detector.

17. The chip of clause 15 or 16, wherein the clamp transistor comprises an NMOS transistor.

18. The chip of any one of clauses 15 to 17, further comprising a second clamp transistor coupled between the first bus and a second bus, wherein the trigger device is coupled to a gate of the second clamp transistor.

19. The chip of clause 18, wherein the first bus comprises a ground bus and the second bus comprises a voltage supply bus.

20. A chip, comprising:
a pad;
an interface circuit coupled to the pad, wherein the interface circuit includes a transistor coupled to the pad;
a trigger device; and
a pass circuit having a first input coupled to the trigger device, and an output coupled to a gate of the transistor.

21. The chip of clause 20, wherein the interface circuit comprises a driver, and the pass circuit has a second input coupled to a predriver.

22. The chip of clause 21, wherein the pass circuit is configured to receive a drive signal from the predriver at the second input and pass the drive signal to the gate of the transistor.

23. The chip of clause 22, wherein the pass circuit is configured to receive a trigger signal from the trigger device at the first input and pass the trigger signal to the gate of the transistor.

24. The chip of clause 20, wherein the pass circuit has a second input, the pass circuit is configured to receive a drive signal or a control signal at the second input, and the pass circuit is configured to pass the drive signal or the control signal to the gate of the transistor.

25. The chip of clause 24, wherein the pass circuit is configured to receive a trigger signal from the trigger device at the first input and pass the trigger signal to the gate of the transistor.

26. The chip of clause 20, wherein the interface circuit comprises an impedance matching network.

27. The chip of clause 26, wherein:
the interface circuit comprises multiple slices having resistors and transistors, each of the slices including a respective one of the resistors and a respective one of the transistors coupled in series; and
the output of the pass circuit is coupled to gates of the transistors in the slices.

28. The chip of clause 27, wherein the pass circuit has a second input, the pass circuit is configured to receive a control signal at the second input, and the pass circuit is configured to pass the control signal to the gates of the transistors in the slices.

29. The chip of clause 28, wherein the pass circuit is configured to receive a trigger signal from the trigger device at the first input and pass the trigger signal to the gates of the transistors in the slices.

30. The chip of any one of clauses 20 to 29, wherein the pass circuit comprises at least one of an OR gate, an AND gate, or a NAND gate.

31. The chip of any one of clauses 20 to 30, further comprising a clamp transistor coupled between a first bus and a second bus, wherein the trigger device is coupled to a gate of the clamp transistor.

32. The chip of clause 31, wherein the first bus comprises a voltage supply bus and the second bus comprises a ground bus.

33. The chip of any one of clauses 20 to 32, wherein the interface circuit further includes a resistor coupled between the pad and the transistor.

34. A method of electrostatic discharge (ESD) protection for an interface circuit coupled to a pad, wherein the interface circuit includes a transistor and a resistor coupled between the pad and the transistor, the method comprising:
during an ESD event, providing a current path between a node and a bus, wherein the node is between the resistor and the transistor.

35. The method of clause 34, wherein the ESD event comprises a charged device model (CDM) event.

36. The method of clause 34 or 35, wherein providing the current path comprises forward biasing one or more diodes coupled between the node and the bus.

37. The method of clause 36, wherein the one or more diodes comprises two or more stacked diodes.

38. The method of any one of clauses 34 to 37, wherein the bus includes a voltage supply bus or a ground bus.

39. The method of any one of clauses 34 to 38, wherein the bus includes a voltage supply bus, and the method further comprises:
detecting the ESD event; and
in response to detecting the ESD event, turning on a clamp transistor coupled between the voltage supply bus and a ground bus.

40. The method of clause 34 or 35, wherein a clamp transistor is coupled between the node and the bus, and providing the current path comprises:
detecting the ESD event; and
in response to detecting the ESD event, turning on the clamp transistor.

41. The method of clause 40, wherein detecting the ESD event comprises detecting the ESD event using a resistor-capacitor (RC) transient detector.

42. A method of electrostatic discharge (ESD) protection for an interface circuit coupled to a pad, wherein the interface circuit includes a transistor and a resistor coupled between the pad and the transistor, the method comprising:
detecting an ESD event; and
in response to detecting the ESD event, turning on the transistor.

43. The method of clause 42, wherein detecting the ESD event comprises detecting the ESD event using a resistor-capacitor (RC) transient detector.

44. The method of clause 42 or 43, further comprising driving a gate of the transistor with a data signal or a control signal.

45. The method of any one of clauses 42 to 44, wherein:
detecting the ESD event comprising generating a trigger signal based on the ESD event; and
turning on the transistor comprises passing the trigger signal to a gate of the transistor.

46. The method of clause 45, wherein generating the trigger signal comprises generating the trigger signal using a resistor-capacitor (RC) transient detector.

47. The method of clause 45 or 46, further comprising passing a drive signal from a predriver to the gate of the transistor.

48. The method of clause 47, wherein the drive signal comprises a data signal or a control signal.

49. The method of clause 47 or 48, wherein:
passing the trigger signal to the gate of the transistor comprises passing the trigger signal to the gate of the transistor using a logic gate; and
passing the drive signal to the gate of the transistor comprises passing the drive signal to the gate of the transistor using the logic gate.

50. The method of clause 49, wherein the logic gate includes an OR gate, an AND gate, or a NAND gate.

51. A method of electrostatic discharge (ESD) protection for an interface circuit coupled to a pad, wherein the interface circuit includes a transistor coupled to the pad, the method comprising:
passing a drive signal to a gate of the transistor;
generating a trigger signal based on an ESD event; and
passing the trigger signal to the gate of the transistor.

52. The method of clause 51, wherein generating the trigger signal comprises generating the trigger signal using a resistor-capacitor (RC) transient detector.

53. The method of clause 51 or 52, wherein the drive signal comprises a data signal or a control signal.

54. The method of any one of clauses 51 to 53, wherein passing the drive signal to the gate of the transistor comprises passing the drive signal to the gate of the transistor using a logic gate.

55. The method of clause 54, wherein passing the trigger signal to the gate of the transistor comprises passing the trigger signal to the gate of the transistor using the logic gate.

56. The method of clause 54 or 55, wherein the logic gate includes an OR gate, an AND gate, or a NAND gate.

It is to be appreciated that the present disclosure is not limited to the exemplary terminology used above to describe aspects of the present disclosure. For example, an I/O pad may also be referred to as an interface pad, an integrated circuit (IC) pad, a pin, or another term. A VDD bus may also be referred to as a voltage supply bus, a voltage supply rail, or another term. A VSS bus may also be referred to as a ground bus or a ground rail.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “approximately”, as used herein with respect to a stated value or a property, is intended to indicate being within 10% of the stated value or property.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a pad;
a driver coupled to the pad, wherein the driver comprises:
an n-type metal oxide semiconductor (NMOS) transistor; and
a first resistor coupled between the pad and the NMOS transistor; and
one or more first diodes coupled between a first node and a first bus, wherein the first node is between the first resistor and the NMOS transistor, and the one or more first diodes are in a forward direction from the first node to the first bus.

2. The chip of claim 1, wherein the one or more first diodes comprise a stack of two or more diodes.

3. The chip of claim 1, further comprising a clamp device coupled between the first bus and a second bus.

4. The chip of claim 3, wherein the first bus comprises a voltage supply bus and the second bus comprises a ground bus.

5. The chip of claim 1, wherein the first bus comprises a ground bus.

6. The chip of claim 1, wherein the first resistor comprises a variable resistor.

7. The chip of claim 1, wherein the driver further comprises:
a p-type metal oxide semiconductor (PMOS) transistor; and
a second resistor coupled between the pad and the PMOS transistor.

8. The chip of claim 7, further comprising one or more second diodes coupled between a second node and the first bus, wherein the second node is between the second resistor and the PMOS transistor, and the one or more second diodes are in the forward direction from the second node to the first bus.

9. The chip of claim 8, wherein the one or more first diodes comprise a first stack of two or more diodes, and the one or more second diodes comprise a second stack of two or more diodes.

10. The chip of claim 8, further comprising a clamp device coupled between the first bus and a second bus.

11. The chip of claim 10, wherein the first bus comprises a voltage supply bus and the second bus comprises a ground bus.

12. The chip of claim 8, wherein the first bus comprises a ground bus.

13. The chip of claim 8, wherein the first resistor comprises a first variable resistor and the second resistor comprises a second variable resistor.

14. A chip, comprising:
a pad;
a driver coupled to the pad, wherein the driver comprises:
a first driver transistor; and
a resistor coupled between the pad and the first driver transistor; and
a first dummy transistor coupled between a first node and a first bus, wherein the first node is between the first resistor and the first driver transistor, a source of the first dummy transistor and a gate of the first dummy transistor are coupled to the first bus, and a drain of the first dummy transistor is coupled to the first node.

15. The chip of claim 14, further comprising a clamp device coupled between the first bus and a second bus.

16. The chip of claim 15, wherein the first bus comprises a voltage supply bus and the second bus comprises a ground bus.

17. The chip of claim 14, wherein the first bus comprises a ground bus.

18. The chip of claim 14, wherein the first resistor comprises a variable resistor.

19. The chip of claim 14, wherein the driver further comprises:
a second driver transistor; and
a second resistor coupled between the pad and the second driver transistor.

20. The chip of claim 19, further comprising a second dummy transistor coupled between a second node and the first bus, wherein the second node is between the second resistor and the second driver transistor, a source of the second dummy transistor and a gate of the second dummy transistor are coupled to the first bus, and a drain of the dummy transistor is coupled to the second node.

21. The chip of claim 20, wherein the first driver transistor comprises an n-type metal oxide semiconductor (NMOS) transistor, and the second driver transistor comprises a p-type metal oxide semiconductor (PMOS) transistor.

22. The chip of claim 21, further comprising a clamp device coupled between the first bus and a second bus.

23. The chip of claim 22, wherein the first bus comprises a voltage supply bus and the second bus comprises a ground bus.

24. The chip of claim 21, wherein the first bus comprises a ground bus.

25. The chip of claim 19, wherein the first resistor comprises a first variable resistor and the second resistor comprises a second variable resistor.
